(19) United States
(12) Patent Application Publication
(10) Pub. No.: US 2024/0402234 A1
(43) Pub. Date: Dec. 5, 2024

(54) METHOD FOR DETERMINING AN OPTIMAL PLACEMENT OF MEASUREMENT UNITS FOR ESTIMATING THE STATE OF A PHYSICAL POWER DISTRIBUTION GRID

(71) Applicant: KRAKEN TECHNOLOGIES LIMITED, London (GB)

(72) Inventors: Omid ALIZADEH-MOUSAVI, Vevey (CH); Panayiotis MOUTIS, New York, NY (US)

(73) Assignee: KRAKEN TECHNOLOGIES LIMITED, London (GB)

(21) Appl. No.: 18/698,761

(22) PCT Filed: Sep. 28, 2022
(86) PCT No.: PCT/IB2022/059216

§ 371 Date: Apr. 4, 2024

(30) Foreign Application Priority Data
Oct. 4, 2021 (EP) 21200782.7

(51) Int. Cl. G01R 31/08

(52) U.S. Cl. CPC G01R 31/086

(57) ABSTRACT

The invention relates to a method for determining an optimal placement of measurement units for estimating the state of a physical power distribution grid. The method comprises a step of searching for measurement-unit placements that are compatible with a State Estimation method that is performed in two stages, first, a Minimum Norm formulation, followed by a Weighted Least Square one.

The present invention relates to a method for determining an optimal placement of measurement units for estimating the state of a power distribution grid, and it relates more particularly to such a method allowing to identify an optimal layout comprising a minimum number of measurement units. According to a second aspect, the invention relates to a method for estimating the state of a power distribution grid, and it relates more specifically to such a method requiring no pseudo-measurements. The methods of the invention allow to identify line congestions in the grid and to estimate the voltage profiles with high accuracy.

### BACKGROUND OF THE INVENTION

Generally speaking, the state of a power system refers to a set of variables, the values of which can be used to compute the values of all other variables of the power system. Examples of such sets of variables are (i) the voltage magnitudes and phase-angles of all nodes, (ii) the current magnitudes and phase-angles of all branches, (iii) the voltage magnitudes of all nodes and the active and reactive power flows of all branches. In this context, State Estimation, or SE, is the process of inferring the state of an electrical power system using a limited number of measured data at certain locations in the system (hereinafter the “grid”). SE can inform system operators about the real-time status of a grid or allow for ‘post-mortem’ analysis of faults, events, and regular operation of the grid. The process of placing measurement devices in a grid relies on the nature of the grid, its characteristics, as well as the requirements of the SE per se. In this sense, a brief review of SE at the distribution grid level and of methods for placing measurement devices is presented.

Most prominent distribution grid SE methods are a quasi-real-time set-up for SE of parts of a distribution grid [1], a current-based three-phase formulation [2], a stochastic-aware weighted-least-squares (WLS) formulation [3], a set-up based on line currents and assisted by end-customers' meter data [4] and a SE that is robust to different measurement latencies [5]. Recent efforts in the field pursue formulations of faster estimators and the use of machine learning. In short, a linear distribution grid SE is proposed in [6], constant distribution grid model coefficients for robust and fast SE are discussed in [7], evolutionary algorithms are employed in [8], and a neural network initializes an optimization-formed SE in [9].

At least two major concerns affect the performance and efficiency of distribution grid SE. These concerns are, on the one hand, the location of the measurement devices in a particular distribution grid and, on the other hand, the extent to which measurement devices may be installed in said particular grid. A proper layout of measurement devices is critical as distribution grids contain numerous nodes and lines; hence extensive deployment of such devices implies prohibiting costs. However, using actual grid measurements is critical to the integrity and accuracy of the performed SE. The actual measurements, even if faulty to a greater or lesser extent (equipment accuracy itself can be a consideration), are Gaussian in their nature. This is a benefit to the SE outputs, as the SE can hedge for measurement errors in a robust manner. Most studies estimate that a coverage between 10-50% of any given feeder is required to adequately perform SE [10, 11]. However, as the underlying electrical grid model makes the SE a non-convex problem that cannot be solved accurately in a meaningful time frame, the accuracy of the estimated state is described in terms of probabilistic bounds [12]. Even if only 10% of a feeder is equipped with measurement devices, the costs may still be prohibitive as the voltage phase angle differences in distribution grids are very small and the measurement accuracy to capture them is costly [14]. Whenever real measurements are not available in sufficient numbers in a distribution grid, this lack can be offset with pseudo-measurements (hereinafter “P/Ms”). P/Ms are forecasts or projections of values based on historical data [15], hence, not necessarily Gaussian in nature [16] and, thus, responsible for much uncertainty in the SE accuracy. Section IV in [17] summarizes over a dozen probabilistic and machine learning based methods seeking to curtail the effects of P/Ms to SE. Moreover, the lack or limited availability of historical data in Distribution Systems may mean that P/Ms cannot be obtained in the first place.

### SUMMARY OF THE INVENTION

It is therefore an object of the present invention to alleviate the above-mentioned problems in the prior art. The present invention achieves this object and others by providing a method for determining an optimal placement of measurement units according to the appended claim 1.

The method of the invention for determining an optimal placement of measurement units takes advantage of the particular way the grid state estimation (SE) is performed. In other word, the method for determining an optimal placement of measurement units for SE, on the one hand, and the SE method as such, on the other hand, are both based on the same inventive concept. According to the invention, the SE method is performed in two stages, first, a Minimum Norm formulation, followed by a Weighted Least Square one. The method for determining an optimal placement of measurement units, and the SE method that it serves, come with theoretical guarantees that line congestions in the grid are captured at a given level of confidence, while the voltage profile of the grid is also estimated with high accuracy.

### BRIEF DESCRIPTION OF THE DRAWINGS

Other features and advantages of the present invention will appear upon reading the following description, given solely by way of non-limiting example, and made with reference to the annexed drawings, in which:

FIG. 1 is a schematic representation of a medium voltage feeder (part of a grid at the distribution level) comprising 20 nodes (or buses), which forms the setting for an exemplary implementation of the method of the invention;

FIG. 2 is a flowchart depicting a particular implementation of the method of the invention for determining an optimal placement of measurement units for estimating the state of a power distribution grid;

FIGS. 3A and 3B are two representations of a standardized normal distribution, the standardized distribution shown in FIG. 3A is divided into 0.5·σ intervals, while the one shown in FIG. 3B is divided into 0.25·σ intervals;

FIG. 4 is a more detailed flowchart depicting a particular implementation of the routine represented by a loop containing boxes 02 and 03 in FIG. 2;

FIG. 5 is a flowchart depicting an alternative version of the implementation depicted in FIG. 4;

FIG. 6 shows an indicative output of an exemplary implementation of the two-stage SE of the invention in one particular operating case of the medium voltage feeder of FIG. 1.

### DETAILED DESCRIPTION OF AN EXEMPLARY IMPLEMENTATION

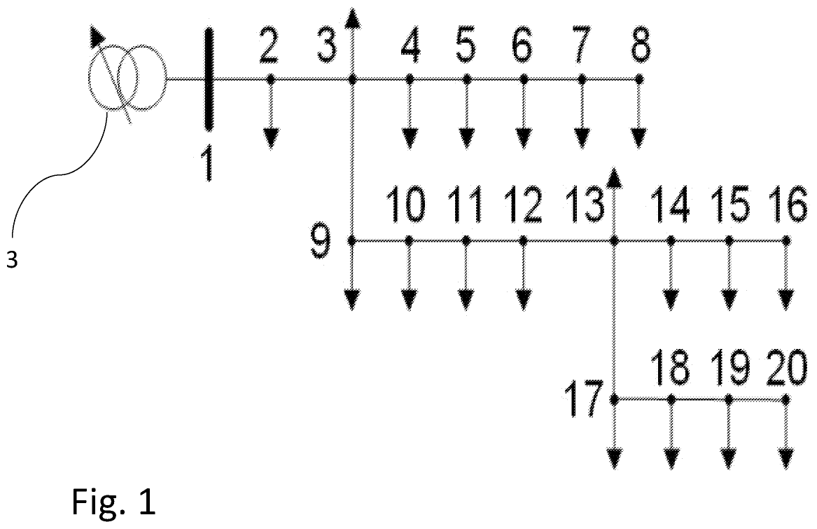

As the field to which the present invention applies is that of electrical power distribution grids, we begin by describing an exemplary distribution grid. An electrical power distribution grid comprises a set of physical nodes (or buses) and a set of physical branches (or lines) for connecting one node to another node. FIG. 1 is a one-line diagram of a “real world” 20-bus medium voltage feeder that forms the backbone of an existing power distribution grid located in Switzerland. Measurements form all the transformers (herein after T/Fs) in the distribution grid were recorded over a whole year with a 10′ resolution. The complete profiles of numerous operating scenarios can be made available from this data. Furthermore, the line impedances and transformer (T/F) ratings of the feeder are also available. These parameters are given in Table I below. In the following description of an exemplary implementation of the method of the invention, the set of variables used for defining the grid state is made up of the nodal voltages and the branch active and reactive powers. One should note however that a person skilled in the art will be capable of adapting the present exemplary implementation to the case where the state of the grid is defined by a different set of variables.

The power distribution grid is not provided with any distributed generation and storage. One will therefore understand that the critical lines for congestion or reverse power flows are the lines nearest to the in-feeding substation (referenced 3)

TABLE I

| Bus i | Bus j | g (S) | b (S) |
|---|---|---|---|
| 1 | 2 | 1.82 | −2.28 |
| 2 | 3 | 17.55 | −12.18 |
| 3 | 4 | 9.51 | −6.81 |
| 3 | 9 | 15.74 | −10.64 |
| 4 | 5 | 15.00 | −9.30 |
| 5 | 6 | 9.90 | −6.11 |
| 6 | 7 | 10.71 | −7.40 |
| 7 | 8 | 11.05 | −4.98 |
| 9 | 10 | 9.35 | −6.40 |
| 10 | 11 | 17.05 | −12.30 |
| 11 | 12 | 6.98 | −4.55 |
| 12 | 13 | 8.92 | −4.15 |
| 13 | 14 | 10.83 | −5.23 |
| 13 | 17 | 13.53 | −8.88 |
| 14 | 15 | 12.78 | −6.34 |
| 15 | 16 | 7.15 | −3.47 |
| 17 | 18 | 19.34 | −9.52 |
| 18 | 19 | 15.12 | −7.44 |
| 19 | 20 | 12.74 | −6.35 |

| Bus No | Sₙ (kW) |
|---|---|
| 1 | — |
| 2 | 630 |
| 3 | 400 |
| 4 | 800 |
| 5 | 1260 |
| 6 | 630 |
| 7 | 400 |
| 8 | 630 |
| 9 | 400 |
| 10 | 250 |
| 11 | 250 |
| 12 | 400 |
| 13 | 800 |
| 14 | 630 |
| 15 | 400 |
| 16 | 250 |
| 17 | 400 |
| 18 | 630 |
| 19 | 630 |
| 20 | 400 |

Estimating the nodal voltages and the branch active and reactive powers defining the state of a power distribution grid requires the presence of a monitoring infrastructure capable of providing synchronized measurements of voltage and current at a plurality of locations in the power grid. Such a monitoring infrastructure comprises measurement units provided at a selection of physical nodes of the network (in the following disclosure, physical nodes of the network that are equipped with a measurement unit are called “measuring nodes”). Each measurement unit may be arranged to measure the voltage at a particular measuring node (called the nodal voltage) and currents flowing into or out of that particular measuring node (called branch currents), the branch currents can either be currents flowing through branches that are incident on that particular measuring node or currents associated with loads or generations at that particular node. The flows of active and reactive power through a branch that is incident on a particular measuring node can be calculated from the nodal voltage, the branch current through that particular branch, and the phase difference between the nodal voltage and the branch current. This computation can implement locally by each one of the measurement units using the following well known relations:

$$P = V \cdot I \cdot cos φ and Q = V \cdot I \cdot sin φ$$

Furthermore, the net sum of all the active branch power flowing into or out of a node is called the nodal active power, and the net sum of all the reactive power flowing into or out of a node is called the nodal reactive power.

A monitoring infrastructure further comprises communication means arranged for communication between the measurement units and at least one processing unit. It should be noted that the communication means does not necessarily comprise a dedicated transmission network. For example, the monitoring infrastructure may rely instead on the commercial cellular network provided by a mobile operator. According to alternative implementations, however, the communication means for the monitoring infrastructure could be of any type that a person skilled in the art would consider adequate (including power line communication for example).

It should be understood however that saying that the data used for state estimation comes from synchronized measurements at a plurality of locations in the power grid, does not mean that the measurement units must necessarily be highly synchronized. Indeed, the measurement units do not need to be expensive Phasor Measurement Units (PMUs) having a permanent link to a common time reference. Conventional measurement devices capable of timing successive measurements using GPS or NTP for a time reference signal are sufficiently accurate.

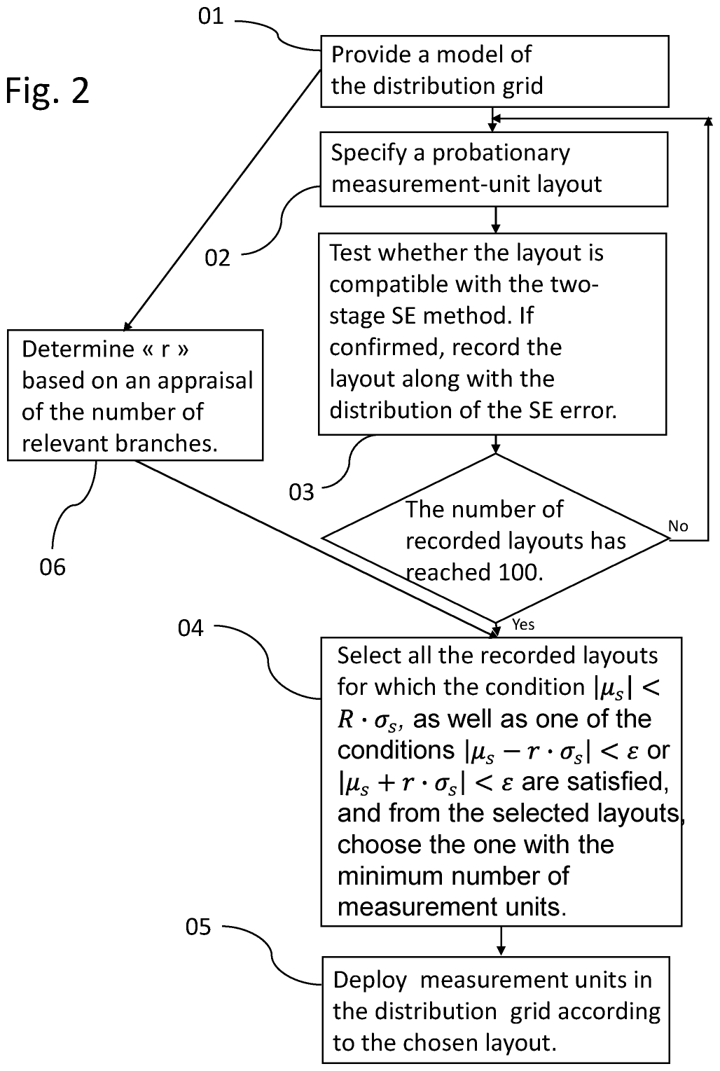

FIG. 2 is a flowchart depicting an exemplary implementation of the method of the invention for determining an optimal placement of measurement units for estimating the state of a power distribution grid. The illustrated flowchart comprises six boxes. The first box (referenced 01) generally represents a preliminary step of providing a model of the power distribution grid to which the method should apply. The complete model of a grid typically comprises the grid's admittance matrix containing the topology of the grid, as well as the conductance and susceptance of the branches connecting the nodes, and further comprises the nominal capacity of every branch as well as of the loads and generations at every node.

The second box (referenced 02) represents the task of specifying a hypothetical monitoring infrastructure for the model of the power distribution grid. The hypothetical monitoring infrastructure comprises at least one randomly placed measurement unit. Any node of the power distribution grid that is equipped with a measurement unit according to the hypothetical monitoring infrastructure is called a “measuring node” of the hypothetical monitoring infrastructure.

The third box (referenced 03) represents the task of assessing whether the placement of the at least one measurement unit of the hypothetical monitoring infrastructure is compatible with the two-stage state estimation (SE) method of the invention. The first stage of the state estimation method consists in implementing a Minimum Norm State Estimation for each scenario comprised in a set of stochastic scenarios of the loads and generations in the power distribution grid. For each particular scenario, the Minimum Norm SE uses “measured data” as input. The “measured data” is actually simulated measured data supposed to come from the nodes of the power distribution grid that are provided with measurement units according to the hypothetical monitoring infrastructure. The “measured data” are computed for each particular scenario of loads and generations. In order for the placement of the at least one measurement unit (i.e. the hypothetical monitoring infrastructure) to be compatible with the two-stage SE method, the result of the first stage must be controllable.

The second stage of the state estimation method consists in implementing a Weighted Least Square (WLS) SE for each scenario comprised in the set of stochastic scenarios. The WLS SE uses the same measured data as the Minimum Norm SE as input. Furthermore, the WLS SE also uses states estimated to have non-zero values in the first stage as input. State variables estimated by the Minimum Norm SE for each scenario in the first stage, and used as input in the second state, are called “estimeasurements” or “E/Ms” in the context of the present two-stage state estimation method. In order for the placement of the at least one measurement unit to be compatible with the two-stage SE method, the result of the second stage must be observable. The third box (box 03) further provides that, if the placement of the at least one measurement unit of the hypothetical monitoring infrastructure is compatible with the two-stage state estimation method, one further computes the second stage state estimation error. If the means μs of the estimation error is smaller than A (i.e |μₛ|<A, with A∈ [symbol] ⁺), and the standard deviation σ_{S} is smaller than B (i.e. |σₛ|<B, with B∈ [symbol] ⁺), the means and the standard deviation of the error are recorded along with the measurement-unit placement (to give an example, typical values for A and B are A=0.15 and B=0.60. These values are given here in p.u., or in other words “per unit”).

The routine consisting in successively implementing the tasks represented in boxes 02 and 03 is repeated until a predefined number of placements (for example one hundred placements) have been recorded. Once the predefined number of placements has been recorded, the method moves on to the fourth box.

The fourth box (referenced 04) generally represents selecting the measurement-unit placements for which the conditions |μₛ±r·σₛ|<ε and |μₛ|<R·σₛ are both satisfied (where μₛ, is the means of the second stage state estimation error, and σₛ is its standard deviation). According to the invention R≤3. Both the condition involving “r” and the condition involving “R” are required by the presently described particular implementation that invention. However, it is important to note that either one, or both, of these the conditions can be dispensed with. Accordingly, neither one of them is present in each and every implementation of the method of the invention. The task represented by the fourth box further comprises choosing from the selected measurement-unit placements, the placement with the minimum number of measurement units.

The fifth box (referenced 05) represents the task of deploying the measurement units in the physical distribution grid according to the chosen placement.

The sixth box (referenced 06) generally represents the task of firstly identifying the branches of the power distribution grid that are significantly exposed to the risk of congestion or inverse power flow, of secondly assessing the percentage ζ of these branches that should be monitored with high accuracy, and of thirdly determining the ratio r of the standard deviation (σₛ) over the means (μₛ) of a normal distribution, such that the percentage of cases in the normal distribution that are contained in a permittance having a width of no more than 0.5·σₛ and that is centered at μₛ±r·σₛ, or in other words at zero, is equal to ζ.

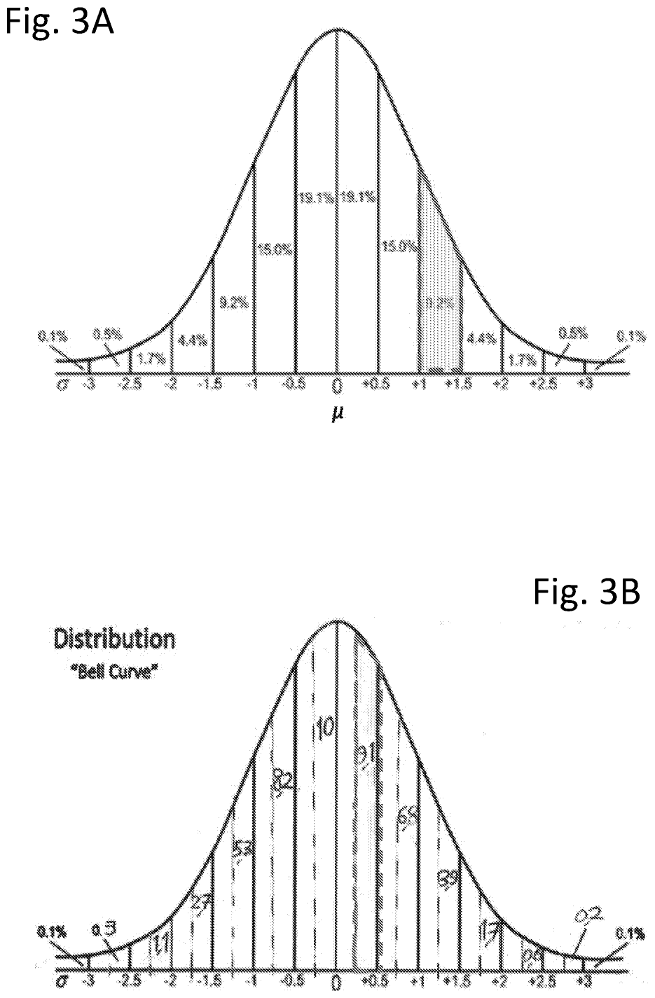

Provided that no pseudo-measurements are used, SE error may be considered to be distributed normally with a statistical mean μ and a variance σ². Furthermore, the error of the subset S, made up of the estimated state variables for the branches that are significantly exposed to congestion or inverse power flow, will also follow normal distribution of mean μ_{S} and variance σ_{S}². If μ_{S}+r·σ_{S} crosses 0, for r∈ [symbol] , then at least ζ<|S| states in S are estimated with high accuracy (low error); e.g. if |S|=100 and μ_{S}+1.25·σ_{S}=0±ε (i.e. r=1.25), then about ζ=9 states have low SE error, because if we consider that a close vicinity of μ_{S}+r·σ_{S}=0 corresponds to the interval [μ_{S}+σ_{S}, μ_{S}+1.5·σ_{S}], it follows that 9.2% of all samples of the normal distribution are in the close vicinity of a μ_{S}+r·σ_{S}=0 (refer to FIG. 3A) (it should be noted that the same analysis also applies if μ_{S}−r·σ_{S} crosses 0). Inversely, if ζ states in S must be estimated accurately, an r may be selected so that, if μ_{S}+r·σ_{S} crosses 0, then the interval [μ_{S}+σ_{S}, μ_{S}+1.5·σ_{S}] contains a portion of |S| equal to ζ.

It should be noted that the value of “r” depends on the width of the interval (hereinafter the “permittance”) that is considered to embody the close vicinity of μ_{S}+r·σ_{S}=0. For example, if instead of being equal to 0.5·σ_{S} as before, the permittance is equal to 0.25·σ_{S}, and the number of states that have to be estimated accurately is still ζ=9, then the estimated value of “r” will be 0.375, because the interval [μ_{S}+0.25·σ_{S}, μ_{S}+0.5·σ_{S}] of a normal distribution contains 9.1% of the cases (refer to FIG. 3B). One will understand that the lower the interval permittance, the smaller the value of “r”. Furthermore as μ_{S}+r·σ_{S}=0, the smaller the value of “r”, the smaller the value of μ_{S}. It follows that if the interval permittance is smaller, the selected placements will require a greater number of measurement units. On the other hand, if the permittance is substantially greater than 0.5·σ_{S}, the number of states that are estimated accurately will be questionable.

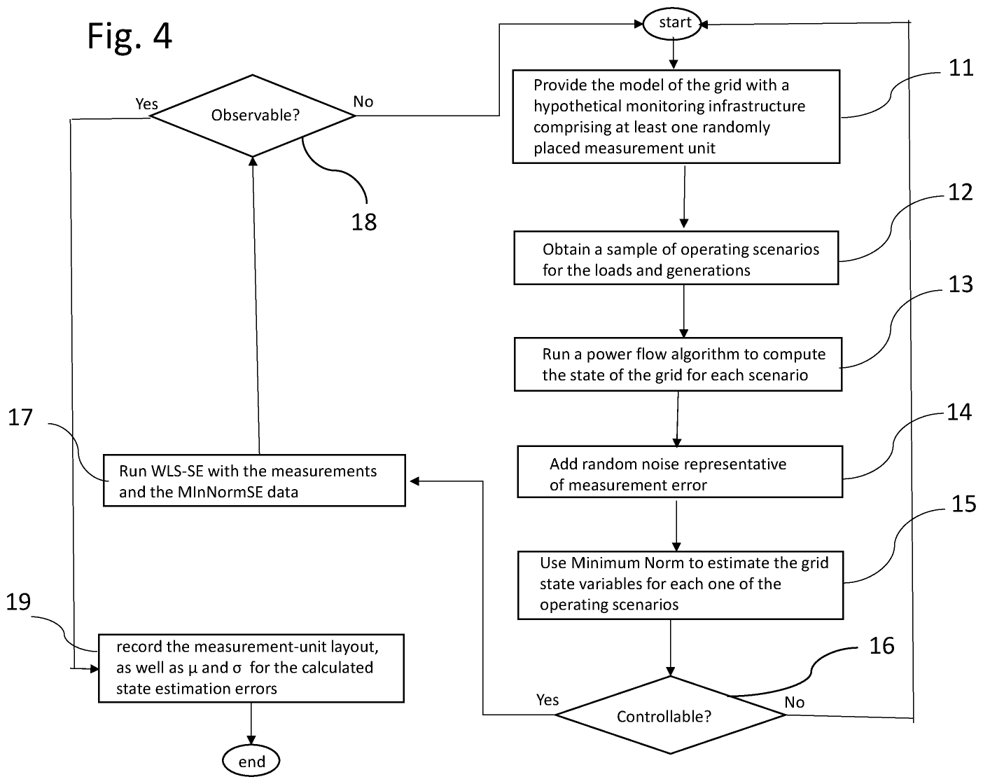

FIG. 4 is a flowchart illustrating in greater detail a particular implementation of the routine represented by a loop containing boxes 02 and 03 of FIG. 2. The first box of FIG. 4 (box 11) is identical to box 02 of FIG. 2.

The second box of FIG. 4 (box 12) consists in the task of obtaining a set of stochastic scenarios for the loads and generations in the power distribution grid. The obtained set should contain at least about 1000 different scenarios for (i.e. operating conditions of) the loads and generations (i.e. demand loading, as well as Distributed Generation and Storage (DGS) if present). The stochastic scenarios for the loads and generations can be obtained either from simulations (for example by running a Monte Carlo) or from actual data (if many measured profiles of loads and generations in the power distribution grid are available).

The third box of FIG. 4 (box 13) consists in running a power flow algorithm in order to simulate the power flow in the modelled distribution grid for each one of the operating scenarios contained in the sample that was obtained during the previous step, and further to compute the state of the power distribution grid for each scenario. The values computed by the power flow algorithm for voltages at measuring nodes of the hypothetical monitoring infrastructure, for currents through branches that are incident on measuring nodes of the hypothetical monitoring infrastructure, as well as for currents associated with power injections at measuring nodes of the hypothetical monitoring infrastructure, are referred to hereafter as “measured values”, and the corresponding values of the active and reactive powers are also referred to as “measured values”.

The fourth box of FIG. 4 (box 14) consists in adding random noise to the “measured values” obtained in the previous step. The added noise should be representative of the accuracy level of the measurement units. For instances, for a measurement device with 99.9% accuracy, the added random noise can be calculated from a normal distribution with a mean value of 0 and standard deviation of 0.1% of the “measured value”.

The fifth box of FIG. 4 (box 15) consists in using Minimum Norm to identify an objective function for the states of the power distribution grid, as well as to estimate the grid state variables for each one of the operating scenarios obtained in the second step. For each scenario, this Minimum Norm SE uses the corresponding measured values obtained in the fourth step as input. As previously noted, the state estimation method of the invention is performed in two stages, first, a Minimum Norm formulation, followed by a Weighted Least Squares one. One will therefore understand that the fifth box (box 15) corresponds to the first stage of the SE.

In the first stage, the SE problem can be formulated as the following

Minimum Norm optimization problem:

find min∥\tilde{x}∥₂

subject to \tilde{x}=\hat{x}

f(\tilde{x},\hat{x})=0
where \tilde{x} is all grid state variables, \hat{x} is the measured values, and the model of power flow equations is given by f(\tilde{x},\hat{x}).

According to an exemplary implementation that does not require using PMUs, the method uses a known power flow approximation that is linear for a radial distribution grid when solved for the square of bus voltage magnitudes [18]. It should be understood however that the present invention does not require using a linear approximation. According to the above-mentioned exemplary implementation, the first stage of the two-stage SE method of the invention is defined as follows:

$$min {‖ {\tilde{V}}_{1}^{2} , ... , {\tilde{p}}_{12} , ... , {\tilde{q}}_{12} , ... , {\tilde{P}}_{1} , ... , {\tilde{Q}}_{1} ... ‖}_{2} \qquad {1}^{st} stage$$

$$s . t . {\tilde{V}}_{i}^{2} = {\hat{V}}_{i}^{2} , {\tilde{P}}_{i} = {\hat{P}}_{i} , {\tilde{Q}}_{i} = {\hat{Q}}_{i} , {\tilde{p}}_{ij} = {\hat{p}}_{ij} , {\tilde{q}}_{ij} = {\hat{q}}_{ij}$$

$$\begin{matrix}{\hat{V}}_{i}^{2} = {\tilde{V}}_{j}^{2} - 2 {\tilde{p}}_{ij} {r}_{ij} - 2 {\tilde{q}}_{ij} {x}_{ij} \\ {\tilde{V}}_{j}^{2} = {\hat{V}}_{i}^{2} - 2 {\tilde{p}}_{ji} {r}_{ji} - 2 {\tilde{q}}_{ji} {x}_{ji} \\ {\tilde{V}}_{i}^{2} = {\tilde{V}}_{j}^{2} - 2 {\hat{p}}_{ij} {r}_{ij} - 2 {\tilde{q}}_{ij} {x}_{ij} \\ {\tilde{V}}_{i}^{2} = {\tilde{V}}_{j}^{2} - 2 {\tilde{p}}_{ij} {r}_{ij} - 2 {\hat{q}}_{ji} {x}_{ij}\end{matrix} \}$$

$$\begin{matrix}{\hat{P}}_{i} = {\tilde{V}}_{i}^{2} real ( {Y}_{ii} ) + \sum {\tilde{p}}_{ij} \\ {\hat{Q}}_{i} = {\tilde{V}}_{i}^{2} imag ( {Y}_{ii} ) + \sum {\tilde{q}}_{ij} \\ {\tilde{P}}_{i} = {\tilde{V}}_{i}^{2} real ( {Y}_{ii} ) + {\sum }_{k \neq i} {\tilde{p}}_{kj} + {\hat{p}}_{ij} \\ {\tilde{Q}}_{i} = {\tilde{V}}_{i}^{2} imag ( {Y}_{ii} ) + {\sum }_{k \neq i} {\tilde{q}}_{kj} + {\hat{q}}_{ij}\end{matrix} \}$$

where V, p, q, r and x are the voltage magnitude, active and reactive power flows, line resistance and reactance, respectively, between buses i and j. Where, beyond the previously defined variables, Y, P and Q denote the DS admittance matrix, active and reactive power injections, respectively, while values under hats denote measured values and those under tildes denote first stage estimated values of state variables (hereinafter “estimeasurements” or “E/Ms”).

The sixth box of FIG. 4 (box 16) represents testing the optimization problem defined in the previous step to assess whether it makes the power distribution grid controllable. If the outcome of the test is negative, the process returns to the first box (box 11) as the previous version of the hypothetical monitoring infrastructure is replaced with a new version. The placement of the measurement units in the new version of the hypothetical monitoring infrastructure must be different from the placement of the measurement units in the previous version. If the outcome of the test is positive, the process moves on to the next step (box 17).

The seventh box if FIG. 4 (box 17) consists in using Weighted Least Square to identify an objective function for the states of the power distribution grid, as well as to estimate the grid state variables for each one of the operating scenarios obtained in box 12. For each scenario, this Weighted Least Square SE uses the corresponding measured values and E/Ms obtained inbox 15 as input. The seventh box corresponds to the second stage of the SE.

In the second stage, the SE problem can be formulated as the following Weighted Least Square problem:

find: min∥x−\tilde{x},x−\hat{x}∥₂,

subject to f(\tilde{x},\hat{x},x)=0
where x is all grid state variables, \tilde{x} is all grid state variables
calculated at stage 1, \hat{x} is the measurement values, and the model of power flow equations is given by f(\tilde{x},\hat{x},x).

According to an exemplary implementation that does not require using PMUs, the second stage of the two-stage SE method of the invention is defined as follows:

$${min ( z - Ay )}^{′} \cdot W \cdot ( z - Ay ) \qquad {2}^{nd} stage$$

$$for y = [ {\tilde{V}}_{1}^{2} , ... , {\tilde{p}}_{12} , ... , {\tilde{q}}_{12} , ... ]$$

$$s . t . Ay = z ⇒ \{ ( 1 ) , ( 2 ) , ( 3 ) , ( 4 ) \}$$

$${V}_{i}^{2} = \{ {\hat{V}}_{i}^{2} ∨ {\tilde{V}}_{i}^{2} ∨ 1 \} , {p}_{ij} = \{ {\hat{p}}_{ij} ∨ {\tilde{p}}_{ij} \} , {q}_{ij} = \{ {\hat{p}}_{ij} ∨ {\tilde{p}}_{ij} \} \qquad ( 1 )$$

$$\begin{matrix}\{ {\hat{V}}_{i}^{2} ∨ {\tilde{V}}_{i}^{2} ∨ 1 \} = {V}_{j}^{2} - 2 {p}_{ij} {r}_{ij} - 2 {q}_{ij} {x}_{ij} \\ {V}_{j}^{2} = \{ {\hat{V}}_{i}^{2} ∨ {\tilde{V}}_{i}^{2} ∨ 1 \} - 2 {p}_{ji} {r}_{ji} - 2 {q}_{ji} {x}_{ji} \\ {V}_{i}^{2} = {V}_{j}^{2} - 2 \{ {\hat{p}}_{ij} ∨ {\tilde{p}}_{ij} \} {r}_{ij} - 2 {q}_{ij} {x}_{ij} \\ {V}_{i}^{2} = {V}_{j}^{2} - 2 {p}_{ij} {r}_{ij} - 2 \{ {\hat{q}}_{ij} ∨ {\tilde{q}}_{ij} \} {x}_{ij}\end{matrix} \} \qquad ( 2 )$$

$$\begin{matrix}\{ {\hat{P}}_{i} ∨ {\tilde{P}}_{i} \} = {V}_{i}^{2} real ( {Y}_{ii} ) + \sum {p}_{ij} \\ \{ {\hat{Q}}_{i} ∨ {\tilde{Q}}_{i} \} = {V}_{i}^{2} imag ( {Y}_{ii} ) + \sum {q}_{ij}\end{matrix} \} \qquad ( 3 )$$

$$- {p}_{ji} = \{ {\hat{p}}_{ij} ∨ {\tilde{p}}_{ij} \} , - {q}_{ji} = \{ {\hat{p}}_{ij} ∨ {\tilde{p}}_{ij} \} \qquad ( 4 )$$

Where, as in the first step, V, p, q, r and x are the voltage magnitude, active and reactive power flows, line resistance and reactance, respectively, between buses i and j; and Y, P and Q denote the DS admittance matrix, active and reactive power injections, respectively, while values under hats denote measured values and those under tildes denote E/Ms. Variables without hats or tildes are the second stage estimated values of the state variables. For the case of voltage magnitude, the nominal voltage may be used as a kind of pseudo-measurement (P/M) (i.e. a P/M of 1 p.u.), if neither a measured value nor an E/M is available.

The eighth box of FIG. 4 (box 18) consists in testing the optimization problem defined in the previous step to assess whether it makes the power distribution grid observable. If the outcome of the test is negative, the process returns to the first box (box 11) as the previous version of the hypothetical monitoring infrastructure is replaced with a new version. The placement of the measurement units in the new version of the hypothetical monitoring infrastructure should be different from the placement of the measurement units in all previous versions. If the outcome of the test is positive, the process moves on to the next step (box 19).

The nineth box (box 19) represents firstly the task of calculating the second stage SE errors for a subset S of the estimated grid state variables (according to some implementations, the subset S may be equal to the entire set of estimated grid state variables). The second stage SE errors can be calculated by comparing the grid state variables estimated in box 17 with the ones previously calculated in box 13. Secondly, box 19 also represents the task of the recording the placement of the measurement units in the current version of the hypothetical monitoring infrastructure, along with the means (μ_{S}) and the standard deviation (σ_{S}) of the calculated second stage SE errors for the subset S of the estimated grid state variables. One will understand that, in case where the subset S is not equal to the entire set of estimated grid state variables, the subset S should comprise the estimated state variables that concern branches of the power distribution grid that were identified earlier as being significantly exposed to congestion or inverse power flow. In the case of implementations of the method that comprise a step of determining “r” (box 06 of FIG. 2), the subset S can be made up of the branches of the power distribution grid that were identified as being significantly exposed to congestion or inverse power flow in the course of determining “r”.

The routine illustrated in FIG. 4 (comprising each of the boxes 11 to 19) is repeated a predetermined number of times (for example one hundred times), so that a predetermined number of measurement-unit placements are recorded along with the values of the means and of the standard deviation of the SE errors associated with that particular measurement-unit placement.

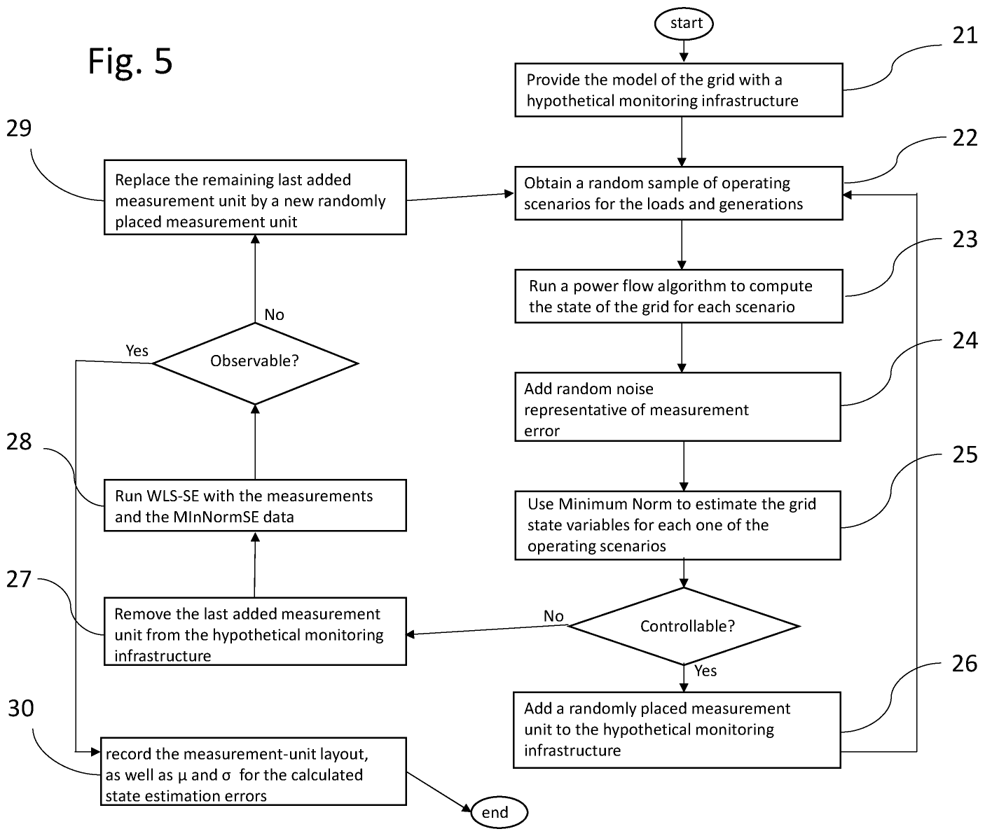

FIG. 5 is a flowchart depicting an alternative version of the exemplary implementation of the method of the invention illustrated by the flowchart of FIG. 4. The tasks represented by boxes 21 to 25 of FIG. 5 can be identical to the boxes represented by boxes 11 to 15 of FIG. 4. Furthermore, boxes 28 and 30 of FIG. 5 can be identical to boxes 17 and 19 of FIG. 4. A first difference between the flowcharts of FIGS. 4 and 5 concerns the effect of the controllability test represented by box 16 in FIG. 4. Indeed, according to FIG. 5, when the outcome of the controllability test is positive, the illustrated implementation returns to box 22 and adds an additional randomly placed measurement unit to the hypothetical monitoring infrastructure, instead of moving on to the second stage of the SE method right away. When the outcome of the controllability test is negative, on the other hand, the last added measurement unit is removed from the hypothetical monitoring infrastructure as indicated by box 27. Removing the last added measurement unit makes the power distribution grid controllable again. The implementation of the method then moves on to the second stage of the SE method represented by box 28.

A second difference between the flowcharts of FIGS. 4 and 5 concerns what happens in the case where the outcome of the observability test represented by box 18 (FIG. 4) is negative. According to FIG. 4, in this case, the process returns to box 11 as previously described, and the current version of hypothetical monitoring infrastructure is replaced by a new version. According to FIG. 5, on the other hand, only one of the measurement units of the current hypothetical monitoring infrastructure is removed and replaced by new randomly placed measurement unit. According to a preferred version of the implementation illustrated by the flowchart of FIG. 5, the measurement unit that is removed and replaced by new randomly placed measurement unit is the remaining last added measurement unit.

### Example

By way of example, we now describe how the method illustrated by the flowchart of FIG. 2 can be applied to the 20-bus medium voltage feeder of FIG. 1. As previously explained, the method begins with the step of providing a model of the distribution grid (Box 01 of FIG. 2). The model of the distribution grid of the present example comprises all the conductances and susceptances listed in Table 1, as well as the nominal capacity of every branch. In the present example, each branch has a nominal capacity equal to 8 MVA.

Measurements from all the T/Fs in this grid over a whole year period in 10′ detail are available (about 53000 entries per T/F). A power flow algorithm is executed to retrieve all operating data for every 10′ interval. The retrieved data provides an objective way of identifying the branches of the power distribution grid that are the most exposed to congestion or reverse power flow. Indeed, these branches are the ones through which pass the highest active and reactive power flows (by absolute value). The identified active and reactive power flows are p₁₋₂ and q₁₋₂ through branch 1-2, p₂₋₃ and q₂₋₃ through branch 2-3, and finally p₃₋₉ and q₃₋₉ through branch 3-9. The subset Sₚ comprises the state variables p₁₋₂, p₂₋₁, p₂₋₃, p₃₋₂, p₃₋₉ and p₉₋₃, and the subset S_{Q} comprises the state variables q₁₋₂, q₂₋₁, q₂₋₃, q₃₋₂, q₃₋₉ and q₉₋₃. The highest active power flows (by absolute value) in the power distribution grid are p₁₋₂, p₂₋₃, p₃₋₉ and the highest reactive power flows (by absolute value) in the power distribution grid are q₁₋₂, q₂₋₃, q₃₋₉. The number of critical active |Sₚ| and reactive |S₀| power flows are therefore both considered to be equal to six (k=6).

As a complete profile is available for numerous operating scenarios of the distribution grid, the power flow data of about 1000 different cases is used to obtain a random sample of operating scenarios of the load, instead of using the results of a (Monte Carlo) simulation (Box 12 of FIG. 4 and Box 22 of FIG. 5).

Among all the recorded measurement-unit placements (box 03 of FIG. 2, box 19 of FIG. 4 and box 30 of FIG. 5), there were 107 placements for which the maximum voltage magnitude estimate error is less than 1%, and the measurement errors for the subsets of state variables S_{P} & S_{Q} meet the conditions of μ_{S}+r·σ_{S} crossing 0 at r≈0.6 (i.e. ζ=1). Table II presents 4 of these measurement placements with their μ_{S} and σ_{S} for active and reactive power flows as well as the average and maximum voltage magnitude estimate errors.

TABLE II

| | | | | ΔVₘₑₐₙ | ΔVₘₐₓ | |
|---|---|---|---|---|---|---|
| \|z\| | | μ | σ | (%) | (%) | Placement |
| 4 | S_{P} | −0.01 | 0.07 | 0.08 | 0.16 | {1, 7, 9, 10} |
| | S_{Q} | −0.14 | 0.54 | | | |
| 7 | S_{P} | 0.02 | −0.24 | 0.05 | 0.14 | {1, 2, 7, 9, 14, 15, 17} |
| | S_{Q} | −0.15 | 0.36 | | | |
| 11 | S_{P} | −0.02 | 0.62 | 0.04 | 0.10 | {1, 5, 7, 9, 10, 11, |
| | S_{Q} | −0.01 | 0.67 | | | 14, 17, 18, 19, 20} |
| 17 | S_{P} | −0.01 | 0.07 | 0.03 | 0.09 | {1, 2, 3, 4, 5, 6, 7, 8, 9, 10, |
| | S_{Q} | −0.01 | 0.05 | | | 12, 13, 14, 16, 17, 18, 20} |

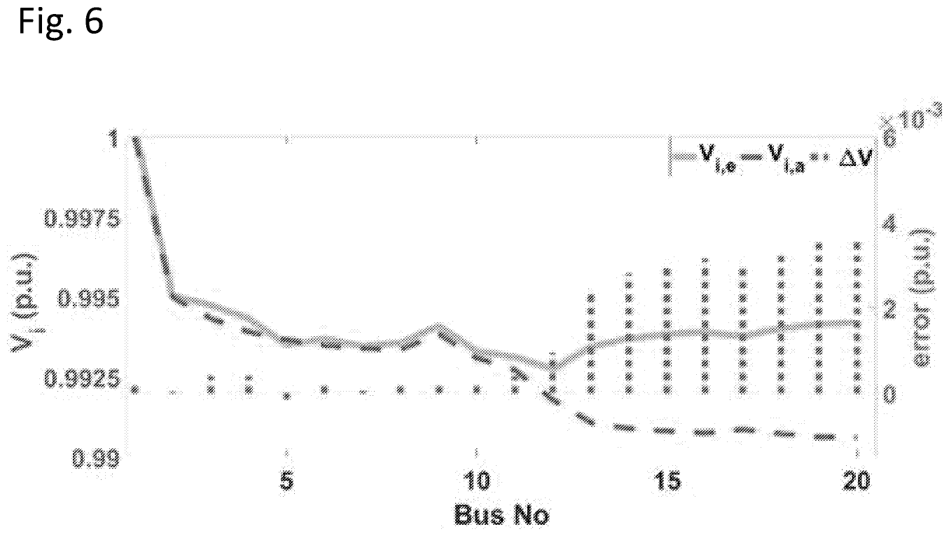

FIG. 6 shows an indicative output of an exemplary implementation of the two-stage SE of the invention in one particular operating case of the medium voltage feeder of FIG. 1. The x-axis in FIG. 6 shows the 20 buses of the feeder, while the y-axis on the left shows the voltages in p.u. (per unit of the nominal voltage), and the y-axis on the right shows the error between estimated and actual values. The estimated voltage profile of every node is given in continuous pink and the actual voltage profile is shown by a red-dashed line. The estimated and actual voltages should be read from y-axis on the left (errors for the estimated voltage are in the order of 10⁻³). The values for the estimation error for every node are shown in dotted brown. These values should be read from the y-axis on the right. One will understand that voltage estimate errors are very small, i.e. less than 0.004 p.u. and that the error is even smaller for the nodes closer to the primary substation (slack node).

### REFERENCES

[1] I. Roytelman and S. Shahidehpour, “State estimation for electric power distribution systems in quasi real-time conditions,” IEEE Transactions on Power Delivery, vol. 8, no. 4, pp. 2009-2015, 1993.
[2] C. Lu, J. Teng, and W.-H. Liu, “Distribution system state estimation,” IEEE Transactions on Power systems, vol. 10, no. 1, pp. 229-240, 1995.
[3] K. Li, “State estimation for power distribution system and measurement impacts,” IEEE Transactions on Power Systems, vol. 11, no. 2, pp. 911-916, 1996.
[4] H. Wang and N. N. Schulz, “A revised branch current-based distribution system state estimation algorithm and meter placement impact,” IEEE Transactions on Power Systems, vol. 19, no. 1, pp. 207-213, 2004.
[5] J. Wu, Y. He, and N. Jenkins, “A robust state estimator for medium voltage distribution networks,” IEEE Transactions on Power Systems, vol. 28, no. 2, pp. 1008-1016, 2013.
[6] D. A. Haughton and G. T. Heydt, “A linear state estimation formulation for smart distribution systems,” IEEE Transactions on Power Systems, vol. 28, no. 2, pp. 1187-1195, 2012.
[7] M. C. de Almeida and L. F. Ochoa, “An improved three-phase AMB distribution system state estimator,” IEEE Transactions on Power Systems, vol. 32, no. 2, pp. 1463-1473, 2016.
[8] S. Prasad and D. V. Kumar, “Trade-offs in PMU and IED deployment for active distribution state estimation using multi-objective evolutionary algorithm,” IEEE Transactions on Instrumentation and Measurement, vol. 67, no. 6, pp. 1298-1307, 2018.
[9] A. S. Zamzam, X. Fu, and N. D. Sidiropoulos, “Data-driven learning-based optimization for distribution system state estimation,” IEEE Transactions on Power Systems, vol. 34, no. 6, pp. 4796-4805, 2019.
[10] J. Liu, J. Tang, F. Ponci, A. Monti, C. Muscas, and P. A. Pegoraro, “Trade-offs in PMU deployment for state estimation in active distribution grids,” IEEE Transactions on Smart Grid, vol. 3, no. 2, pp. 915-924, 2012.
[11] J. Liu, F. Ponci, A. Monti, C. Muscas, P. A. Pegoraro, and S. Sulis, “Optimal meter placement for robust measurement systems in active distribution grids,” IEEE Transactions on Instrumentation and Measurement, vol. 63, no. 5, pp. 1096-1105, 2014.
[12] R. Singh, B. C. Pal, and R. B. Vinter, “Measurement placement in distribution system state estimation,” IEEE Transactions on Power Systems, vol. 24, no. 2, pp. 668-675, 2009.
[13] J. A. Taylor, Convex optimization of power systems. Cambridge University Press, 2015.
[14] A. von Meier, E. Stewart, A. McEachern, M. Andersen, and L. Mehrmanesh, “Precision micro-synchrophasors for distribution systems: A summary of applications,” IEEE Transactions on Smart Grid, vol. 8, no. 6, pp. 2926-2936, 2017.
[15] A. Monticelli, “Electric power system state estimation,” Proceedings of the IEEE, vol. 88, no. 2, pp. 262-282, 2000.
[16] P. A. Pegoraro et al., “Bayesian approach for distribution system state estimation with non-Gaussian uncertainty models,” IEEE Transactions on Instrumentation and Measurement, vol. 66, no. 11, pp. 2957-2966, 2017.
[17] K. Dehghanpour, Z. Wang, J. Wang, Y. Yuan, and F. Bu, “A survey on state estimation techniques and challenges in smart distribution systems,” IEEE Transactions on Smart Grid, vol. 10, no. 2, pp. 2312-2322, 2018.
[18] L. W. Gan, S. H. Low, and Ieee, “Convex Relaxations and Linear Approximation for Optimal Power Flow in Multiphase Radial Networks”, 2014 Power System Computation Conference (Pscc), 2014.

1. A method for detecting and localizing faults in a medium voltage (MV) and low voltage (LV) distribution grid comprising a plurality of MV and LV nodes and a plurality of MV and LV branches, as well as several MV/LV transformers each arranged to connect one MV node with one LV node, the MV and LV distribution grid further being provided with a monitoring infrastructure comprising metering devices assigned to particular LV nodes of the distribution grid, each of one of said metering devices being arranged to measure a nodal voltage of the LV node to which it is assigned and a current flowing into or out of said LV node through an upstream branch incident on said LV node, each one of said particular LV nodes preferably being one of the nodes that a MV/LV transformer is arranged to connect with a MV node, the monitoring infrastructure further comprising a central processing unit and a communication means arranged for allowing communication between the metering devices and the central processing unit; wherein the method comprises the following steps:
I. measuring, by the metering device at each one of said particular LV nodes, the voltage v(t) and the current i(t) with a sampling rate that is high enough for sampling said voltage and said current over a bandwidth with an upper limit of at least 1 kHz.
II. calculating, by the metering device at each one of said particular LV nodes, using the voltages and the currents measured in step I, for each one of a succession of evaluation time windows, the mean value of the nodal negative-sequence voltage (V_{neg}), and further calculating a variation of the calculated mean value with respect to the previous evaluation time window,
III. assessing, by the metering device at each one of said particular LV nodes, the following first criterion for each one of the evaluation time windows except the first one: “the variation of the mean value of the nodal negative-sequence voltage (V_{neg-rltv}) calculated in step II is larger than a first given threshold”, and, when the assessment comes out positive for a particular evaluation time window, sending, by the metering device, a fault notification comprising the calculated variation for the particular evaluation time window to the central processing unit; and
IV. identifying, by the central processing unit using fault notifications received during a predefined time lag window from metering devices assigned to different LV nodes, the fault location with the help of grid topology information.

2. The method for detecting and localizing faults in a medium voltage (MV) and low voltage (LV) distribution grid of claim 1, wherein step II further comprises calculating, by the metering device at each one of said particular LV nodes using the voltages and currents measured in step I, for each one of the evaluation time windows, mean values of at least one variable selected from the group consisting of the nodal voltages for all three phases (V₃ₚₕ₋ᵣₗₜᵥ), the nodal voltage harmonics (Vₕᵣₘ) as the maximum of the voltage harmonics of all three phases at every multiple of the fundamental frequency comprised in a range between 150 Hz and 1000 Hz, the branch active and reactive powers for all three phases (P₃ₚₕ, Q₃ₚₕ), the branch admittance for all three phases (Y₃ₚₕ), and the “QP ratio” (QPᵣₐₜᵢₒ) defined as
$$cos ( a tan ( \frac{{\overline{Q}}_{3 ph}}{{\overline{P}}_{3 ph}} ) ) ,$$
where Q̅₃ₚₕ and P̅₃ₚₕ are the sums of the three phases of Q₃ₚₕ and P₃ₚₕ respectively, and further calculating variations of the calculated mean values with respect to the previous evaluation time window; and
wherein the method further comprises an additional step (step III_prior), implemented between step II and step III, step III_prior allowing to identify a fault-type by having the metering device at each one of said particular LV nodes, for each one of the evaluation time windows except the first one, separately check for the occurrence of a 3-phase fault in any part of the distribution grid, for the occurrence of a 2-phase or single-phase fault in the LV part of the distribution grid, and for the occurrence of a 2-phase fault in the MV part of the distribution grid and, whenever the occurrence of a fault of any one of said fault-types is confirmed for a particular evaluation time window, further having the metering device send a fault notification for the particular evaluation time window to the central processing unit and have the method go directly to step IV, if no fault is detected during step III-prior for a particular evaluation time window, the method goes on to step III, and
wherein any fault notification sent by a metering device during step III is interpreted by the central processing unit as concerning a single-phase fault in the MV part of the distribution grid.

3. The method for detecting and localizing faults in a medium voltage (MV) and low voltage (LV) distribution grid of claim 2, wherein step III_prior comprises a sub step (sub step III_a) consisting in having the metering device at each one of said particular LV nodes use the variations of the mean values calculated in step II, in order to check for the occurrence of a 3-phase fault in any part of the distribution grid, whenever this occurrence is confirmed for a particular evaluation time window, have the metering device send a fault notification comprising the variations calculated for the particular evaluation time window to the central processing unit and jump to step IV.

4. The method for detecting and localizing faults in a medium voltage (MV) and low voltage (LV) distribution grid of claim 3, wherein sub step III_a comprises a sub step (sub step D1) of the metering device assessing the two following criteria for each one of the time windows except the first one: (i) “the variation of the mean value of branch admittance calculated in step II (Y₃ₚₕ₋ᵣₗₜᵥ) is larger than a fourth given threshold for all three phases” and (ii) “the variation of the “QP ratio” calculated in step II (QPᵣₐₜᵢₒ₋ᵣₗₜᵥ) is larger than a fifth given threshold”, if both assessments come out positive for a particular evaluation time window, the occurrence of a 3-phase fault in the LV part of the distribution grid is confirmed.

5. The method for detecting and localizing faults in a medium voltage (MV) and low voltage (LV) distribution grid of claim 3, wherein sub step III_a comprises a sub step (sub step D2) of the metering device assessing the two following criteria for each one of the time windows except the first one: (i) “the variation of the mean value of the nodal voltage calculated in step II (V₃ₚₕ₋ᵣₗₜᵥ) is less than a third given threshold for all three phases” and (ii) “the variation of the mean value of the branch active power calculated in step II (P₃ₚₕ₋ᵣₗₜᵥ), and summed over the three phases, is less than a second given threshold”, if both assessments come out positive for a particular evaluation time window, the occurrence of a 3-phase fault in the MV part of the distribution grid is confirmed.

6. The method for detecting and localizing faults in a medium voltage (MV) and low voltage (LV) distribution grid claim 3, wherein step III_prior comprises a sub step (sub step III_b) consisting in having the metering device at each one of said particular LV nodes use the variations of the mean values calculated in step II, in order to check for the occurrence of a 2-phase or a single-phase fault in a LV part of the distribution grid, whenever this occurrence is confirmed for a particular evaluation time window, have the metering device send a fault notification comprising the variations calculated for the particular evaluation time window to the central processing unit and jump to step IV.

7. The method for detecting and localizing faults in a medium voltage (MV) and low voltage (LV) distribution grid of claim 6, wherein sub step III_b comprises a sub step (sub step D3) of the metering device assessing the two following criteria for each one of the time windows except the first one: (i) “the variation of the mean value of branch admittance calculated in step II (Y₃ₚₕ₋ᵣₗₜᵥ) is larger than the fourth given threshold for two phases” and (ii) “the variation of the “QP ratio” calculated in step II (QPᵣₐₜᵢₒ₋ᵣₗₜᵥ) is larger than the fifth given threshold”, if both assessments come out positive for a particular evaluation time window, the occurrence of a 2-phase fault in a LV part of the distribution grid is confirmed.

8. The method for detecting and localizing faults in a medium voltage (MV) and low voltage (LV) distribution grid of claim 6, wherein sub step III_b comprises a sub step (sub step D4) of the metering device assessing the two following criteria for each one of the time windows except the first one: (i) “the variation of the mean value of branch admittance calculated in step II (Y₃ₚₕ₋ᵣₗₜᵥ) is larger than a fourth given threshold for one phase” and (ii) “the variation of the “QP ratio” calculated in step II (QPᵣₐₜᵢₒ₋ᵣₗₜᵥ) is larger than a fifth given threshold”, if both assessments come out positive for a particular evaluation time window, the occurrence of a single-phase fault in a LV part of the distribution grid is confirmed.

9. The method for detecting and localizing faults in a medium voltage (MV) and low voltage (LV) distribution grid of claim 6, wherein step III_prior comprises a sub step (sub step III_c) consisting in having the metering device at each one of said particular LV nodes use the variations of the mean values calculated in step II, in order to check for the occurrence of a 2-phase fault in the MV part of the distribution grid, whenever this occurrence is confirmed for a particular evaluation time window, have the metering device send a fault notification comprising the variations calculated for the particular evaluation time window to the central processing unit and jump to step IV.

10. The method for detecting and localizing faults in a medium voltage (MV) and low voltage (LV) distribution grid of claim 9, wherein sub step III_c comprises a sub step (sub step D5) of the metering device assessing the two following criteria for each one of the time windows except the first one: (i) “the variation of the mean value of the nodal voltage calculated in step II (V₃ₚₕ₋ᵣₗₜᵥ) is less than the third given threshold for two phases” and (ii) “the variation of the mean value of the branch active power calculated in step II (P₃ₚₕ₋ᵣₗₜᵥ), and summed over the three phases, is less than the second given threshold”, if both assessments come out positive for a particular evaluation time window, the occurrence of a 2-phase fault in the MV part of the distribution grid is confirmed.

11. The method for detecting and localizing faults in a MV and LV distribution grid of claim 9, wherein sub step III_b is implemented after sub step III_a, and sub step III_c is implemented after sub step III_b.

12. The method for detecting and localizing faults in a MV and LV distribution grid of claim 1, wherein step III further comprises having the metering device at each one of said particular LV nodes, further assess the following second criterion for each one of the evaluation time windows except the first one: (ii) “the variation of the mean value of the nodal voltage harmonics calculated in step II (Vₕᵣₘ₋ᵣₗₜᵥ) is larger than a sixth given threshold”, if the first and the second assessment both come out positive for a particular evaluation time window, the occurrence of a single-phase fault in the MV part of the distribution grid is validated.

13. The method for detecting and localizing faults in a MV and LV distribution grid of claim 1, wherein the method further estimates the distance of a metering device to the fault location by interpolating the electrical distance and the calculated variations between the identified metering device closest to the fault and its neighboring metering devices.

14. The method for detecting and localizing faults in a MV and LV distribution grid of claim 1, wherein the mean values of variables are calculated by the Fourier transformation of voltage and current measurements at the fundamental frequency and other frequencies higher than the distribution grid's nominal frequency.

15. The method for detecting and localizing faults in a MV and LV distribution grid of claim 1, wherein each one of said particular LV nodes is one of the nodes that a MV/LV transformer is arranged to connect with a MV node.

16. The method for detecting and localizing faults in a MV and LV distribution grid of claim 1, wherein the communication means is a preexisting commercial network provided by a mobile operator.

17. The method for detecting and localizing faults in a MV and LV distribution grid of claim 1, wherein the metering devices are synchronized by means of the Network Time Protocol (NTP) via the communication means.

18. The method for detecting and localizing faults in a MV and LV distribution grid of claim 1, wherein one of the metering devices serves as the central processing unit.
